(19) United States
(12) Patent Application Publication
(10) Pub. No.: US 2025/0075898 A1
(43) Pub. Date: Mar. 6, 2025

(54) VAPORIZER

(71) Applicant: Proterial, Ltd., Koto-ku, Tokyo (JP)

(72) Inventor: Akinori SAWADA, Mie-gun (JP)

(21) Appl. No.: 18/721,958

(22) PCT Filed: Dec. 22, 2021
(86) PCT No.: PCT/JP2022/046349

§ 371 Date: Jun. 20, 2024

(30) Foreign Application Priority Data
Dec. 22, 2021 (JP) 2021-207905

(51) Int. Cl. F22B 1/28; H01L 21/67; H05B 3/06

(52) U.S. Cl. CPC F22B 1/28; H01L 21/67017; H05B 3/06

(57) ABSTRACT

This vaporizer includes a flow channel through which a material gas flows, one or more replaceable heaters which heat the flow channel, a manipulator which is connected with the heater and displaces the heater in a direction approaching the flow channel or in a direction going away from the flow channel, a guide which determines a movable region of the heater, and a stopper which fixes a positional relation between the manipulator and the guide. Preferably, at least a part of the manipulator exists at a position which can be directly touched with a finger of a hand through an opening part which appears by detaching an opening surface of a case.

### FIELD

This invention relates to a vaporizer used for manufacture of a semiconductor device.

### BACKGROUND

In a manufacturing process of a semiconductor device represented by an integrated circuit, various kinds of semiconductor material gas (which will be referred to as a “material gas” hereafter) is used according to a purpose of the process. A precursor stored in a liquid or solid state among precursors of the material gases is supplied to a semiconductor manufacturing apparatus after being changed to a material gas in a gaseous state using a vaporizer via piping. As a means for generating a material gas from a precursor in a vaporizer, for example, there is a method for heating the precursor stored in the tank to generate vapor, etc. Generally, a valve for starting or stopping supply of the generated material gas and a flow controller for controlling a flow rate of the material gas, etc. are built into a vaporizer.

In association with progress of a production technology of an integrated circuit, opportunity in which a new material gas which has lower equilibrium vapor pressure and therefore is less likely to be vaporized as compared with conventional material gases is used is increasing (for example, in Japanese Patent Application Laid-Open (kokai) No. 2009-74108 (“PTL1”). In a case where such a new material gas is used, when the temperature of the material gas falls in a process in which the material gas is supplied to a semiconductor manufacturing apparatus from a vaporizer, there is a possibility that the material gas may condense to return its precursor in a liquid or solid state and/or the precursor adhering to an inner wall of a flow channel of the material gas may be dried and solidified and, thereafter, exfoliate from the inner wall to become a cause of particles. Therefore, for the purpose of preventing the condensation and solidification of a material gas within a flow channel, it has been attempted to prepare a heater in the circumference of a flow channel of a material gas to warm the flow channel.

It is preferable that the heater is prepared in a state in which the heater can be detached from and attached to the flow channel such that the heater can be replaced easily when the heater breaks down. For example, in the Japanese Patent Application Laid-Open (kokai) No. 2020-153513 (“PTL2”), invention of a flow controller which can hold a heater detachably and in close contact with a side surface of a flow channel consisting of a body member in a block shape is described. Moreover, for example, in the Japanese Patent Application Laid-Open (kokai) No. 2020-159445 (“PTL3”), invention of a flow controller which can mount a heater by pressing the heater on a side surface of a gas line with a gas flow channel prepared inside using an elastic fixing implement in a shape of a clip is described. By building a flow controller according to such conventional technologies into a vaporizer, supply of a material gas generated in a tank can be started and stopped and the supply amount thereof can be controlled while preventing condensation and solidification of the material gas.

### SUMMARY

In some aspects, the techniques described herein relate to a vaporizer for vaporizing a precursor of a material gas for semiconductor manufacture to generate said material gas, including: a flow channel through which said material gas flows, one or more replaceable heaters which heat said flow channel and are installed at a position where it is difficult or impossible for an operator performing maintenance of said vaporizer to directly touch said heaters with a finger of a hand of said operator, a manipulator which is connected with said heater and displaces said heater in a direction approaching said flow channel or in a direction going away from said flow channel, and at least a part of said manipulator exists at a position where said operator can directly touch said manipulator with a finger of a hand of said operator, a guide which determines a movable region of said heater, and a stopper which fixes a positional relation between said manipulator and said guide.

In some aspects, the techniques described herein relate to a vaporizer, further including a case which houses said flow channel, said heaters, said manipulator, said guide and said stopper, wherein: said case has at least one opening surface which can be detached even in a state where another vaporizer or other structure is installed adjacent to said vaporizer, said heaters are installed at a position where it is difficult or impossible for said operator to directly touch said heaters with a finger of a hand of said operator through an opening part which appears by detaching said opening surface, in a state where a positional relation between said manipulator and said guide is fixed by said stopper, and at least a part of said manipulator exists at a position where said operator can directly touch said manipulator with a finger of a hand of said operator through said opening part. In some aspects, the techniques described herein relate to a vaporizer, wherein: at least a part of said manipulator exists on a side of said opening surface from a position 30 mm away toward the inside of said case from said opening surface. In some aspects, the techniques described herein relate to a vaporizer, wherein: said manipulator is constituted by a cylindrical member, said guide is constituted by a rod-shaped member which can be inserted in said cylindrical member to displace said cylindrical member and has a male screw at an end part, and said stopper is constituted by a nut which has a female screw corresponding to said male screw and fixes said cylindrical member to said rod-shaped member by being screwed to the end part of said rod-shaped member.

In some aspects, the techniques described herein relate to a vaporizer, wherein: said manipulator is constituted by a rod-shaped member, said guide is constituted by a cylindrical member in which said rod-shaped member can be inserted to displace said rod-shaped member, and said stopper is constituted by a cap which fixes said rod-shaped member to said cylindrical member by being fixed at the end part of said cylindrical member.

In some aspects, the techniques described herein relate to a vaporizer, wherein: said manipulator is constituted by two extended parts extending from respective end parts of a set of two sheets of said heaters in the same in-plane directions as those of said heaters, said guide is constituted by both side surfaces of said flow channel and a left side surface and a right side surface located outside of said both sides surface of said flow channel among surfaces of said case, and said stopper is constituted by said opening surface and a connection part which connects said extended parts.

In some aspects, the techniques described herein relate to a vaporizer, wherein: said flow channel includes a vaporization part which vaporizes said precursor to generate said material gas, said heater is constituted by one or more planar heaters which heat said vaporization part, said manipulator is constituted by a heater plate connected with said heater, said stopper is constituted by a locking part prepared on a side further from said opening surface and a fastening part prepared on a side closer to said opening surface, and said heater is fixed to a surface of said vaporization part by fastening said fastening part on the surface of said vaporization part.

In some aspects, the techniques described herein relate to a vaporizer, wherein: said flow channel includes a vaporization part which vaporizes said precursor to generate said material gas, said vaporization part includes one or more insertion holes, said heater is constituted by one or more rod-shaped cartridge heaters inserted in said insertion holes, said manipulator is constituted by a lead wire which said cartridge heater includes, said stopper is constituted by a cover that is a tabular member including a small hole through which said lead wire is inserted, and said cartridge heater is fixed to said insertion hole by fastening said cover on a surface of said vaporization part.

In some aspects, the techniques described herein relate to a vaporizer, wherein: said flow channel includes a vaporization part which vaporizes said precursor to generate said material gas and precursor supply piping which supplies said precursor to said vaporization part, said heater is constituted by one or more planar heaters which heat said precursor supply piping, said manipulator is constituted by a heater plate connected with said heater, said stopper is constituted by a pin prepared on a fixing surface that is a surface opposite to said opening surface of said case and an opening hole formed on a side closer to said fixing surface of said heater plate, and a positional relation between said heater plate and said precursor supply piping is fixed by inserting said pin in said opening hole.

In some aspects, the techniques described herein relate to a vaporizer, wherein: said flow channel includes one or more members chosen from a group consisting of a pressure gauge, a valve, a flow controller and a joint block.

In some aspects, the techniques described herein relate to a vaporizer, wherein: a distance between the surface of said flow channel and the surface of said heater is 0.10 mm or more and 0.80 mm or less, in a state where the positional relation between said manipulator and said guide is fixed by said stopper.

In some aspects, the techniques described herein relate to a vaporizer, wherein: electric wiring and tube existing in a movable region of said heater are configured so as to be able to temporarily evacuate from said movable region of said heater by deformation of themselves or release of a connector.

### BRIEF DESCRIPTION OF DRAWINGS

FIG. 1 is a perspective diagram for showing an example of a vaporizer according to the present invention.

FIG. 2 is a schematic diagram for showing an example of a piping system of the vaporizer according to the present invention.

FIG. 3 is a perspective diagram for showing an example of a heater which heats a flow channel.

FIG. 4 is a perspective diagram for showing an example of a flow channel.

FIG. 5 is an erection diagram for showing a state where the heater in FIG. 3 is mounted on the flow channel in FIG. 4.

FIG. 6 is a perspective diagram for showing another example of the heater which heats the flow channel.

FIG. 7 is a perspective diagram for showing an example of a heater which heats a vaporization part.

FIG. 8 is a perspective diagram for showing a tank which constitutes a vaporization part.

FIG. 9 is a perspective diagram for showing a cartridge heater.

FIG. 10 is a perspective diagram for showing a state where two cartridge heaters are built into a vaporizer.

FIG. 11 is a perspective diagram for showing an example of a heater which heats precursor supply piping.

### DETAILED DESCRIPTION

### Technical Problem

In recent years, as the manufacturing process of a semiconductor device is complicated, a technology trends in which numerous kinds of material gases are properly used or the same kind of a material gas is supplied independently to a plurality of position on a silicon substrate has been seen. For this reason, it is demanded to install larger number of vaporizers in one set of semiconductor manufacturing apparatus as compared with conventional semiconductor manufacturing apparatus. However, there is a limitation in the area in which vaporizers can be installed. Therefore, it has been attempted to increase the number of vaporizers without increasing the area in which vaporizers are installed by making the width of a vaporizers narrower than before and installing many vaporizers in a crowded state.

In the vaporizers installed in the crowded state, a range in which the inside of the vaporizers can be accessed for the purpose of maintenance such as replacement of a heater is limited to an opening surface on a front side and positions within a certain distance from the opening surface. When the flow controllers according to the conventional technologies described in PTL2 and PTL3 are built into a vaporizer, since positions of a fixing implement, etc. required to be operated for replacement of a heater are at more inside and deeper than the above-mentioned range, it is impossible or quite difficult to access them. For this reason, when a heater breaks down, it is impossible to replace only the heater easily, and therefore the whole vaporizer must be replaced. Therefore, there was a problem that the required number of vaporizers with a price several tens times or several hundreds times higher than a price of a heater as materials must be provided for backup, and therefore economic burden becomes larger.

Moreover, when replacing a heater through an opening surface in a case where the width of a vaporizer has downsized to 50 mm or less, a space through which a heater can pass is narrower than before. Furthermore, piping and/or electric wiring, etc. are installed close to the opening surface. For this reason, there is a problem that it is extraordinarily difficult to put on and out the heater.

The present disclosure has been conceived in view of the above-mentioned problems, and one of the objectives the present disclosure is to realize vaporizers in which a heater can be replaced easily even in a case where the width of the vaporizers is narrow and the vaporizers are installed densely.

### Solution to Problem

In one embodiment, the present disclosure relates to a vaporizer for vaporizing a precursor of a material gas for semiconductor manufacture to generate said material gas, comprising a flow channel through which a material gas flows, one or more replaceable heaters which heat the flow channel, a manipulator which is connected with the heater and displaces the heater in a direction approaching to the flow channel or in a direction going away from the flow channel, a guide which determines a movable region of the heater, and a stopper which fixes a positional relation between the manipulator and the guide. In the above-mentioned configuration, a heater can be smoothly displaced by the action of the manipulator and the guide. Therefore, when the heater failed, the failed heater can be easily replaced with a heater for backup. Moreover, since the relative positional relation between the heater and the flow channel is fixed by the action of the guide and the stopper, operation of the vaporizer is stabilized.

In another embodiment, the present disclosure relates to a vaporizer further comprising a case which houses the flow channel, the heaters, the manipulator, the guide and the stopper, wherein the case has at least one opening surface which can be detached even in a state where another vaporizer or other structure is installed adjacent to the vaporizer, and at least a part of the manipulator exists at a position which can be directly touched with a finger of a hand through an opening part which appears by detaching the opening surface, in a state where a positional relation between the manipulator and the guide is fixed by the stopper (which will be mentioned later in detail) In this configuration, since an operator can operate at least a part of the manipulator using a finger of a hand through the opening part, a heater can be easily replaced in a short time.

### Advantageous Effects of Invention

In accordance with the present disclosure, since a heater in a vaporizer can be easily replaced even in a crowded installation situation, the maintainability of the vaporizer can be improved and the expense required for backup apparatus can be reduced largely.

### DESCRIPTION OF EMBODIMENTS

### 1. Configuration Common to Each Embodiment

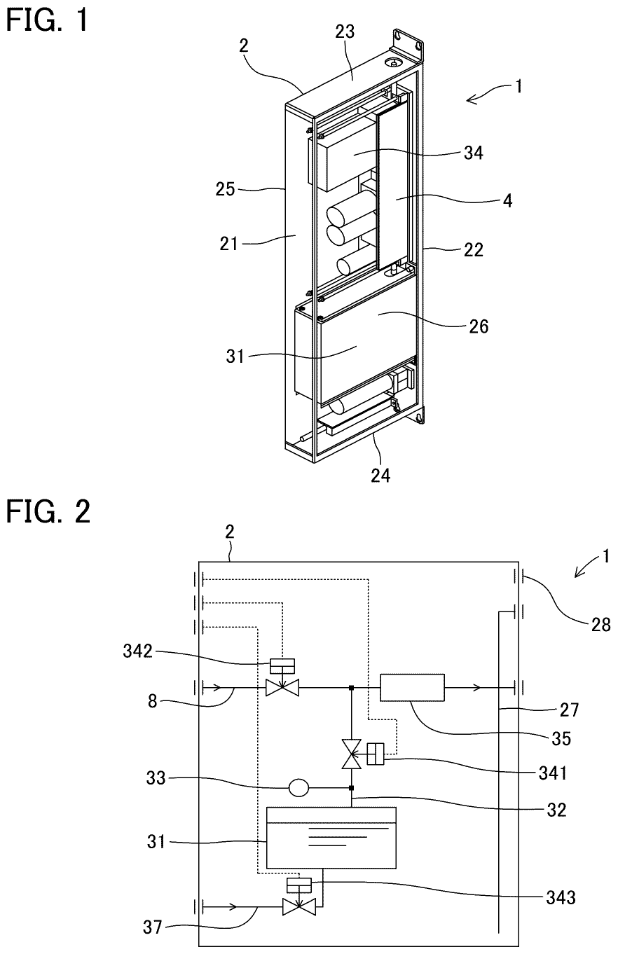

Common configurations of vaporizers according to the present invention will be explained using FIG. 1 and FIG. 2. The present invention is an invention which relates to a vaporizer for generating a material gas by vaporizing a precursor of the material gas for semiconductor manufacture. The precursor before being vaporized may be in a liquid state or in a solid state. The precursor is vaporized by the vaporizer of the present invention to become the material gas, and the generated material gas is supplied to semiconductor manufacturing apparatus for use in the manufacture of semiconductors.

### <Vaporization Part>

As mentioned above, means for generating a material gas from a precursor in a vaporizer includes a method in which the precursor stored in a tank is heated to generate vapor, for example. However, the means for generating a material gas in the vaporizer according to the present invention is not limited to this means, and various known methods can be used. Inside the vaporizer according to the present invention, there is a part constituting some means having a function for generating a material gas by vaporizing a precursor. In the following description, a term “vaporization part” will be adopted as a term for comprehensively expressing such a part.

### <Case>

FIG. 1 is a perspective diagram for showing an example of a vaporizer 1 according to the present invention. In the vaporizer 1 exemplified in FIG. 1, the entire of a vaporization part 31 and other component parts is housed in a case 2 having a vertically long rectangular shape. Among surfaces constituting the case 2, the surface located on the front side of FIG. 1 is an opening surface 21 configured to be removable. The surface located on the opposite side of the opening face 21 across the vaporization part 31 is a fixing surface 22. The vaporizer 1 is fixed in a posture shown in FIG. 1 by the fixing surface 22 being fixed to an installation surface consisting of a vertical wall surface. Other surfaces constituting the case 2 are an upper surface 23, a lower surface 24, a left side surface 25 and a right side surface 26. Each of the surfaces constituting the case 2 can be detachably attached to a frame of the case 2. In FIG. 1, the opening surface 21 and the right side surface 26 are depicted as transparent such that the component parts constituting the vaporizer 1 can be illustrated. As mentioned later, the case is not an essential matter specifying the present invention.

As mentioned above, there is a demand to install a larger number of vaporizers in a single semiconductor manufacturing apparatus than before. For this reason, a plurality of vaporizers having a rectangular shape which is narrow in width may be installed side by side without gaps in a width direction, just as if a plurality of books were lined up on a bookshelf in a stand without gaps. In such a densely installed situation, neighbor vaporizers are installed close to the left side surface 25 and the right side surface 26 of the case 2. In addition, other structures other than the vaporizers may be installed close to the left side surface 25 or the right side surface 26 of the most end of the densely installed multiple vaporizers. In these cases, even when the left side surface 25 and the right side surface 26 are configured to be removable, the left side surface 25 or the right side surface 26 cannot be removed to access the inside of the vaporizer 1 unless the adjacent vaporizer or structure is removed.

A direction in which the inside of the vaporizer can be accessed without removing adjacent vaporizers or structures is a direction from either the opening surface 21, the upper surface 23 or the lower surface 24. However, since the vaporizer 1 has a vertically long rectangular shape, the entire inside of the vaporizer 1 cannot be accessed from the directions from the upper surface 23 and lower surface 24. Therefore, the direction available for maintenance is substantially limited to the direction from the opening surface 21.

The opening surface 21 is usually fixed to the frame of the case 2 by screws or other fixing means. When maintenance of the vaporizer 1 becomes necessary, the inside of the vaporizer 1 can be exposed by releasing the fixing means and detaching the opening surface 21 from the case 2. In the present specification, the “opening part” refers to an open space which appears by removing the opening face 21 of the case 2. In the opening part, the inside of the vaporizer 1 can be accessed through the opening part since the outside and inside of the vaporizer 1, which were separated by the opening surface 21, are connected by removing the opening surface 21. As mentioned above, the width of the vaporizer 1 is narrow, for example, less than 50 mm, and therefore the width of the opening surface 21 is narrow correspondingly. In addition, various component parts are contained inside the case 2 of the vaporizer 1. For this reason, an accessible range to the inside of vaporizer 1 through the opening part is limited.

In the present specification, the “accessible range” means a range which an operator performing maintenance of the vaporizer 1 can directly touch with a finger of a hand of the operator. In the present invention, the “range which can be directly touched with a finger of a hand” includes a range which can be touched with a finger of a hand wearing a glove in a clean room or the like. A range which cannot be directly touched with a finger of a hand and can be operated only with a tool such as a pair of tweezers or a long-handled screwdriver does not fall under the accessible range in the present specification. During the maintenance of the vaporizer 1, if parts constituting the vaporizer 1 can be operated while directly touching them with the finger of the operator's hand, accuracy of the operation will be improved and time period required for the maintenance will be reduced. Namely, maintainability is improved. One of the purposes of the present invention is to improve the maintainability of the vaporizer 1 in installation situations where the accessible range is limited.

### <Flow Channel>

A term “flow channel” in the present specification refers to a pathway through which a material gas flows or a member constituting the pathway. FIG. 2 is a schematic diagram for showing an example of a piping system of the vaporizer 1 according to the present invention. In the example shown here, the vaporization part 31 is constituted by a tank, and a precursor is stored in the tank. The precursor in the tank is heated by a heater (not shown) and evaporates to generate a material gas. The generated material gas is led to the outside of the case 2 of the vaporizer 1 through a gas supply piping 32 arranged to start from the upper surface of the tank, and is supplied to a semiconductor manufacturing apparatus through a piping outside the vaporizer 1. The vaporization part 31 and the gas supply piping 32 is equivalent to a flow channel 3 in the present invention. The flow channel 3 is one of targets to be heated by a heater in the present invention.

For the purpose of measuring or controlling a flow of a material gas, the flow channel 3 through which the material gas flows can be provided with some component parts. A pressure gauge 33 measures a pressure of the material gas flowing through the flow channel 3. A first valve 341 starts or stops the supply of the material gas. A flow controller 35 measures a flow rate of the material gas and controls the flow rate at a desired flow rate. When these component parts are installed in the flow channel 3, a part among these component parts, through which the material gas flows, is included in the gas supply piping 32 and is a target to be heated by the heater.

The vaporizer 1 according to the present invention can be provided with a flow channel purge piping 8. The flow channel purge piping 8 has a function for introducing a purge gas from the outside the vaporizer 1 into the flow channel 3 through which the material gas flows, and discharging the material gas remaining in the flow channel 3 to the outside of the vaporizer 1. For example, an inert gas such as nitrogen gas or argon gas can be used as the purge gas. By installing a second valve 342 between the flow channel purge piping 8 and the flow channel 3 through which the material gas flows, the both can be shut off except when purging the flow channel 3. The flow channel purge piping 8 is not equivalent to the flow channel 3 through which the material gas flows in the present invention. However, it is permissible in the present invention to heat the flow channel purge piping 8 with a heater for some purpose.

The vaporizer 1 according to the present invention can be provided with a precursor supply piping 37. The precursor supply piping 37 has a function for supplying a new precursor to the vaporization part 31 from the outside of the vaporizer 1 when the liquid precursor stored in the vaporization part 31 is consumed by the operation of the vaporizer 1. The precursor supply piping 37 can also be used to take out the precursor remaining in the vaporization part 31 to the outside. The precursor supply piping 37 can be arranged to start from a precursor introduction port provided on the surface of the case 2 and end at a bottom surface of the vaporization part 31, for example. The precursor supply piping 37 may be included in the flow channel 3 in the present invention. By providing the precursor supply piping 37 with a third valve 343, the supply or withdrawal of the precursor can be started or stopped. The precursor supply piping 37 may be heated for the purpose of draining the precursor remaining in the precursor supply piping 37 out of the vaporizer 1. In this case, the precursor supply piping 37 is also a target to be heated by the heater.

Even when the precursor leaks out of the vaporization part 31 for some reason, damage to the vaporizer 1 and impact on the external environment can be minimized by filling the inside of the case 2 with a purge gas such as an inert gas. For this purpose, the vaporizer 1 of the present invention a case purge piping 27 can be provided with a case purge piping 27. As exemplified in FIG. 2, by disposing an outlet of the case purge piping 27 at a position close to a bottom part in the inside of the case 2 and disposing an exhaust hole 28 at a position close to an upper part of the case 2, a purge gas can be filled into the case from the bottom part of the case 2 and the air in the case can be exhausted out through the exhaust hole 28. Alternatively, depending on properties such as a density of the air in the case to be discharged, by providing the outlet of the case purge piping 27 at a position close to the upper part inside the case 2 and providing the exhaust hole 28 at a position close to the bottom part of the case 2, on the contrary to the above, the purge gas may be filled into the case from the upper part of the case 2 and the air in the case may be discharged out through the exhaust hole 28.

As above-mentioned first valve 341, second valve 342 and third valve 343, a normally closed type air valve driven by compressed air can be adopted, for example. A solenoid coil can be used to control the compressed air which drives the air valves. By constituting the solenoid coil as a separate unit from the vaporizer 1 and connecting the unit installed outside the vaporizer 1 with the air valves inside the vaporizer 1 via piping, the width of the vaporizer itself can be made narrower to reduce the installation area. In the vaporizer 1 exemplified in FIG. 2, three ports are provided on the surface of case 2 to receive piping from the solenoid coil, and piping indicated by dotted lines is connected from these ports to the air valves. Although the piping is not a target to be heated by the heater, they may be obstacles to displacement of the heater when the heater is replaced.

### 2. First Embodiment

### <Heater>

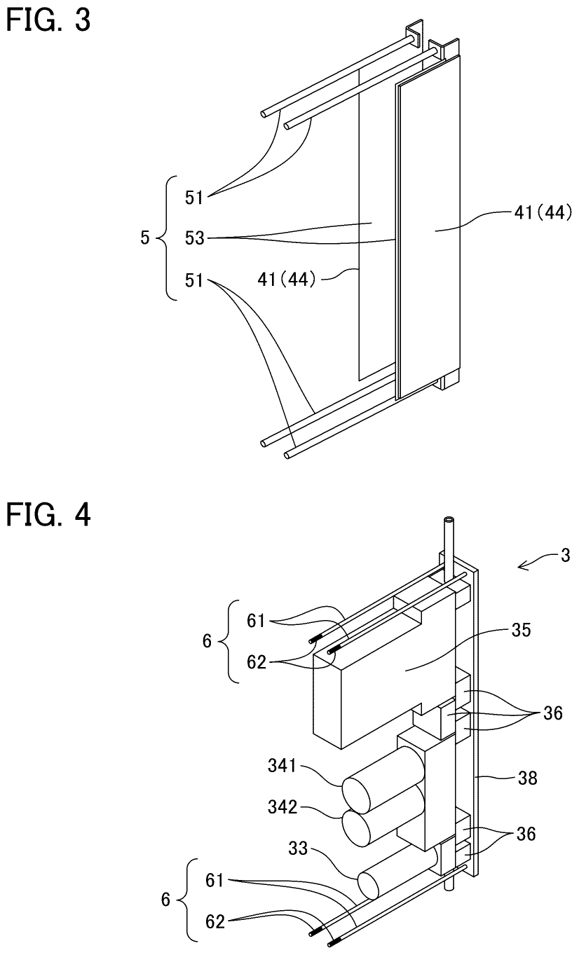

The first embodiment of the present invention is explained using FIG. 3 to

FIG. 6. The vaporizer 1 according to the first embodiment of the present invention comprises one or more replaceable heaters 4 which heat the flow channel 3. FIG. 3 is a perspective diagram for showing an example of a heater 41 which the vaporizer 1 according to the first embodiment of the present invention comprises. The heater 41 is constituted by one or more heating members and is configured so as to be replaceable. In the present specification, “replaceable” with respect to the heater 4 means not only that the heater 4 can be simply attached to and detached from the flow channel, but also that the heater 4 can be replaced even in a situation where direct access to the heater 4 is difficult or impossible, such as a situation where the entire vaporizer 1 is housed in the case 2, for example.

When a part of one or more of the heaters 4 in the vaporizer 1 according to the first embodiment of the present invention fails to perform its original function due to malfunction, the function of the heater 4 can be quickly restored by replacing the failed heater 4 with another heater 4 preliminarily prepared as a backup heater. Thereby, even when a defect occurs in the heater 4 of the vaporizer 1, materials and time required for functional recovery can be reduced since it is not necessary to replace the entire vaporizer, but only the failed heater 4.

The heater 41 exemplified in FIG. 3 is designed to heat the gas supply piping 32 which is a part of the flow channel 3 through which the material gas flows. The heater 41 is constituted by two planar heating elements provided in such a way as to sandwich the gas supply piping 32 arranged in a vertical direction as shown in the figure from both sides. As the heating elements constituting the heater 41, rubber heaters 44 can be adopted, for example. The heater 41 is connected with a cable (not shown) for supplying electric power. The heater 41 can further be provided with a thermostat to prevent excessive temperature rising and a temperature sensor to measure the temperature, and the like. When the heater 41 is constituted by a set of two pieces of heating elements, these two pieces may be replaced at the same time, or only one of the two pieces which has failed may be replaced, when replacing the heater 41.

In the present invention, all of the one or more heaters which the vaporizer 1 comprises may be replaceable heaters, or the one or more heaters may include fixed heaters which are fixed to the vaporizer 1 and cannot be easily replaced. In the latter case, one or more of the multiple heaters which the vaporizer 1 comprises are replaceable heaters. In addition, all of the one or more heaters which the vaporizer 1 comprises may heat the flow channel 3, or the one or more heaters may include a heater which heats a part other than the flow channel.

### <Manipulator>

The vaporizer 1 according to the first embodiment of the present invention comprises a manipulator 5. In the present invention, a “manipulator” refers to a member which can be operated by a human's hand, is connected to the heater 4, and displaces the heater 4 in a direction toward or away from the flow channel 3. The “operation by a human's hand” specifically refers to, but is not limited to, pushing or pulling a part of the manipulator 5 in a state where the part is pinched by two or more fingers of the hand, or pushing a part of the manipulator 5 with a finger cushion of the hand. As mentioned above, the vaporizer 1 according to the first embodiment of the present invention is often installed in a situation where the accessible range is limited. Even in such a situation, the heater 4 installed at a position where it is difficult or impossible to access the heater 4 can be easily replaced by operating the manipulator 5 linked with the heater 4. It is permissible in the present invention to operate the manipulator 5 by a gloved hand.

Heater plates 53 consisting of a metal plate having the same size as the heaters 41 is connected to the heaters 41 exemplified in FIG. 3. The heater plate 53 is located inside the heater 41, i.e., on a side where the flow channel 3 exists. At an end part of the heater 41, a part of the heater plate 53 protrudes from a position of the heater 41 to form a small piece. A cylindrical member 51 is connected to that part of the small piece. Namely, the heater 41 exemplified in FIG. 3 can be displaced by the manipulator 5 constituted by the heater plate 53 and the cylindrical member 51. It is desirable that both of the cylindrical member 51 constituting manipulator 5 and a rod-shaped member 61 constituting a guide 6 which will be mentioned later are constituted by straight members in order to displace the heater 4 smoothly. However, it is permissible in this embodiment to slightly curve shapes of the cylindrical member 51 and the rod-shaped member 61 for some purpose.

The length of the cylindrical member 51 is configured to be about the same as the length of the depth of the vaporizer 1. Thereby, an end part of the cylindrical member 51 linked with the heater 41 via the heater plate 53 can be exposed to the opening part of the case 2, even when the heater 41 is located close to the flow channel 3 existing close to the fixing surface 22 of the vaporizer 1. Therefore, by pinching and pulling the end part of the cylindrical member 51 with fingers of a hand through the opening part, the failed heater 41 can be displaced away from the flow channel 3 and removed from the vaporizer 1. The heater 41 can be displaced in a direction approaching to the flow channel 3 and installed in the vaporizer 1 by pushing the end part of the cylindrical member 51 linked with another heater 41 for replacement through the opening part with a finger of a hand. The set of two heaters 41 exemplified in FIG. 3 may be configured as independently displaceable members, or the set of two heaters 41 may be configured as an inseparably integrated unit linked by a connecting member.

### <Guide>

FIG. 4 is a perspective diagram for showing an example of the gas supply piping 32, namely the flow channel 3, which the vaporizer 1 according to the first embodiment of the present invention comprises. The gas supply piping 32 exemplified here is constituted by a pressure gauge 33, a first valve 341 and a flow control device 35 in order from the upstream side. In FIG. 4, a second valve 342 which constitutes the flow channel purge piping 8 is also depicted. All of the component parts are joined with each other by a joint block 36 which comprises an internal flow channel. The entire flow channel 3 is fixed to one side of a base plate 38 which has an elongated shape with a width slightly smaller than that of the vaporizer 1. At four corners of the base plate 38, guides 6 constituted by rod-shaped members 61 are provided. The guides 6 define a movable range of the heater 4 displaced by the manipulator 5, namely a range in which the heater 41 linked with the manipulator 5 is displaced. A male screw 62 is provided at an end part of the rod-shaped member 61 for fixing a stopper 7 which will be mentioned later.

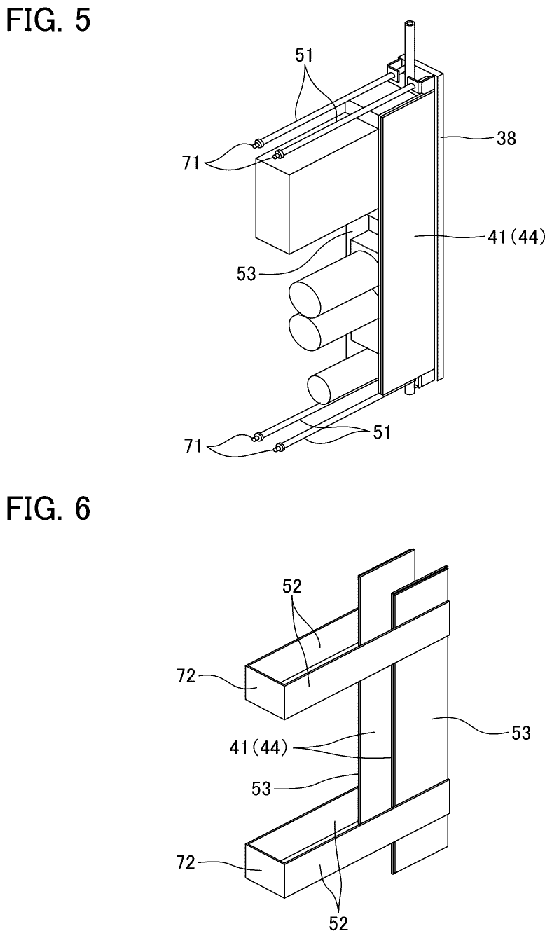

FIG. 5 is an erection diagram for showing a state where the heater in FIG. 3 is built into the flow channel shown in FIG. 4. In order to build the heater 41 into the flow channel 3, first, the end parts of the set of two cylindrical members 51 on the side connected to the small pieces of heater plates 53 are inserted into the end parts of the two guides 6 consisting of the rod-shaped members 61, respectively. Next, the two opposite end parts of the cylindrical members 51 are respectively pinched with fingers of both hands, and slid along the guides 6 while balancing the two cylindrical members 51, and pushed until the end parts of the heaters 41 touch the base plate 38. These operations displace the heater 41 in a direction approaching to the flow channel 3. When removing the heaters 41, the heaters 41 are displaced away from the flow channel 3 by pinching and pulling out the two end parts of the cylindrical members 51 with fingers of both hands, respectively, in a direction opposite to the above.

In any of the above-mentioned operations, since the manipulator 5 is displaced along the guides 6, movable ranges of the heaters 41 are determined in advance according to positions where the guides 6 is installed. Therefore, even when the heaters 41 must be displaced in narrow gaps between the flow channel 3 and the case 2, the heaters 41 can be moved smoothly without contact with the flow channel 3 or the case 2. In addition, even when the base plate 38 is located close to the flow channel 3, tips of the guides 6 can be exposed in the opening part of the case 2. This allows for easy replacement of the heater 41. Furthermore, since the manipulator 5 and the guides 6 are constituted by thin rod-shaped materials, there is little risk that heat generated by the heaters 41 may be transmitted through the manipulator 5 and the guides 6 and needlessly released to the outside of the vaporizer 1.

In a state where the heaters 41 are built into the flow channel 3 shown in FIG. 5, when a distance between the flow channel 3 and the heater 41 is 0.10 mm or more, they will not come into contact, and when the distance is 0.80 mm or less, heat transfer from the heater 41 to the flow channel 3 will not be prevented. Therefore, it is preferable that the distance between the flow channel 3 and the heater 41 is 0.10 mm or more and 0.80 mm or less. A more preferable range for the distance between the flow channel 3 and the heater 41 is 0.20 mm or more and 0.60 mm or less. When the heater 41 is adhered to the heater plate 53 and the heater plate 53 is located on the side where the flow channel 3 exists as exemplified in FIG. 3, the above-mentioned distance between the flow channel 3 and the heater 41 shall be read as the distance between the flow channel 3 and the heater plate 53.

### <Stopper>

The vaporizer 1 according to the first embodiment of the present invention comprises a stopper 7 which fixes a positional relation between the manipulator 5 and the guide 6. The stopper 7 maintains a state where the heater 4 has been displaced in a direction approaching to the flow channel 3 by the action of the manipulator 5. By releasing the fixation by the stopper 7, the heater 4 can be displaced away from the flow channel 3. In FIG. 5 for showing the first embodiment of the present invention, the manipulator 5 has been pushed along the guide 6 to the depth, and the heater 41 is located at a position close to the flow channel 3. However, since the manipulator 5 can be easily displaced along the guide 6, there is a possibility that the heater 41 may be misaligned and it may become impossible to heat the flow channel 3 efficiently when the vaporizer 1 is subjected to external vibration. By using the stopper 7, the positional relation between the manipulator 5 and the guide 6 can be fixed to prevent the heater 4 from moving away from the flow channel 3. When replacing the heater 4, the heater 4 can be removed by releasing the stopper 7 fixed to the guide 6.

In FIG. 5, an example of a stopper 7 constituted by a nut 71 is exemplified. This nut 71 can press a tip of the manipulator 5 toward the back side (depth side) of the vaporizer 1 and fix the positional relation between the manipulator 5 and the guide 6 by being screwed into the male screw 62 provided at the tip of the guide 6 shown in FIG. 4. For this purpose, the length of the guide 6 and the manipulator 5 should be adjusted such that the tip of the guide 6 protrudes slightly from the tip of the manipulator 5 at a position where the heater 41 is fixed. As the stopper 7, the configuration with the nut 71 and the male screw 62 as mentioned above, as well as clips and other known configurations, can be adopted.

In an embodiment of the present invention, the vaporizer 1 further comprises a case which houses the flow channel 3, the heater 4, the manipulator 5, the guide 6 and the stopper 7. The case 2 has at least one opening surface 21 which can be removed even when another vaporizer or other structure is installed adjacent to the vaporizer 1. In a state where the positional relation between the manipulator 5 and the guide 6 is fixed by the stopper 7, at least a part of the manipulator 5 exists at a position where the part can be directly touched with a finger of a hand through the opening part which appears by removing the opening surface 21. In this embodiment, since at least a part of the manipulator 5 exists at a position where the part can be directly touched with a finger of a hand through the opening part, at least a part of the manipulator 5 exists in an accessible range in the above-mentioned meaning. Since an operator performing maintenance of the vaporizer 1 can directly touch at least a part of the manipulator 5 with a finger of a hand as mentioned above, accuracy of the replacement of the heater 4 is improved and the time period required for the maintenance can be reduced. In other words, maintainability is improved.

In another embodiment of the present invention, at least a part of the manipulator 5 exists at a position closer to the opening surface 21 than a position 30 mm apart from the opening surface 21 toward the inside of the case 2. The position 30 mm apart from a position of the opening surface 21 toward the inside of the case 2 in a direction perpendicular to the opening surface 21 can be more easily accessed among positions closer to the opening surface 21 where the manipulator 5 can be accessed. Therefore, when at least a part of the manipulator 5 exists at such a position, the heater 4 can be replaced more easily. It is further preferable that at least a part of the manipulator 5 exists at a position at a position closer to the opening surface 21 than a position 20 mm apart from the opening surface 21 toward the inside of the case 2. It is most preferable that at least a part of the manipulator 5 exists at a position at a position closer to the opening surface 21 than a position 10 mm apart from the opening surface 21 toward the inside of the case 2.

In an embodiment of the present invention, it is more preferable that not only at least a part of the manipulator 5 exists at a position which can be directly touched with a finger of a hand through the opening part which appears by removing the opening surface 21, but also the stopper 7 exists at an equivalent position. Although specific members constituting the stopper 7, such as screws and nuts, are usually operated using tools, it may be more convenient to use a finger of an operator's hand for attaching and detaching these members to and from the guide 6.

### <Modification 1>

Unlike the configuration of the embodiments shown in FIG. 3 to FIG. 5, the guide 6 may be constituted by a cylindrical member and the manipulator 5 may be constituted by a rod-shaped member which is slid and displaced inside the cylindrical member. In this case, the guide 6 may be provided with a slit continuously extending between its two end parts and a member connecting the manipulator 5 and the heater 4 through the slit. The stopper 7 may be constituted by a cap which can be fixed to an end part of the cylindrical member on the opening surface 21 side.

### <Modification 2>

FIG. 6 is a perspective diagram for showing another example of the heater 41 which heats the flow channel 3. The example of the heater 41 shown here belongs to the first embodiment like the example of the heater shown in FIG. 3, and is a modification in which a part of the configuration of the heater shown in FIG. 3 is modified. The heater 41 is constituted by one or more heating members and is connected to a heater plate 53 made of a metal plate with the same size as the heater 41. However, unlike the heater shown in FIG. 3, in the heater 41 shown in FIG. 6, the heater 41 is adhered at a further inner position than the heater plate 53, namely, on the side where the flow channel 3 exists. Therefore, since the heater 41 can be brought closer to the flow channel 3, the heater 41 can heat the flow channel 3 more efficiently.

The set of the two heater plates 53 shown in FIG. 6 is connected with extended parts 52 extending from the end parts of the heaters 41 in an in-plane direction identical to the heaters 41. In addition, the set of two pieces of the extended parts 52 is connected by connection parts 72. Parts of the extended parts 52, specifically end parts on the side of the connection parts 72, exists at positions which can be directly touched with a finger of a hand through the opening part which appears by removing the opening surface 21 of the case 2 in a state where the heater 41 is built in the vaporizer 1, and therefore the parts of the extended parts 52 are accessible. By operating the extended part 52 or a part of the connection part 72 with a finger of a hand, the heater 41 linked to the heater plate 53 can be displaced in a direction approaching to or receding from the flow channel 3.

In this modification, the heaters 41 can be displaced through gaps between the left side surface 25 and right side surface 26 of the case (not shown) and the two side surfaces of the flow channel 3. Since a movable range of the heater 41 is defined by this gap, the left side surface 25 and right side surface 26 of the case 2 and both side surfaces of the flow channel 3 are equivalent to the guides in the present invention. In addition, since the connection parts 72 hit the inside of the opening surface 21 and do not protrude outwards from the case 2 in a state where the opening surface 21 of the case 2 is closed, the connection parts 72 and the opening surface 21 are equivalent to the stopper in the present invention. Since this modification can thus be constituted only by flat plates, this modification can be manufactured easily and reduce costs.

### 3. Second Embodiment

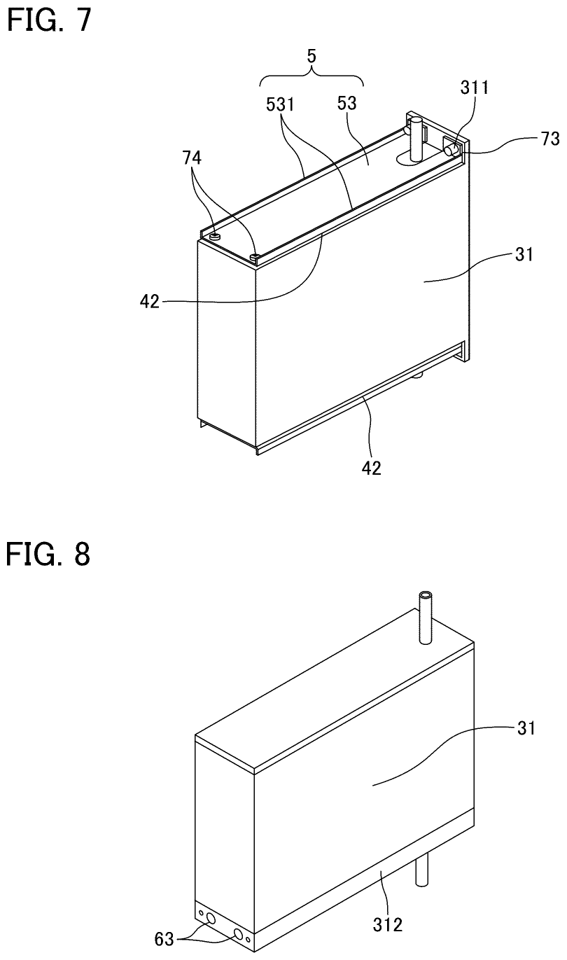

A second embodiment of the present invention will be explained using FIG. 7. FIG. 7 is a perspective diagram for showing an example of a heater 42 which heats a vaporization part 31. Although the vaporization part 31 in the second embodiment can be constituted by a tank as exemplified in FIG. 7, the vaporization part 31 can be constituted by something other than a tank as mentioned above. The heater 42 is constituted by one or more planar heaters and is disposed at one or more locations in the vaporization part 31. It is preferable to dispose the heater 42 at a position where the heater 42 can be easily replaced. Specifically, it is preferable to dispose the heater 42 on an upper surface, lower surface or surface furthest from the gas supply piping 32, of the vaporization part 31. Since a surface of the vaporization part 31 closest to the gas supply piping 32 among surfaces which the vaporization part 31 has cannot be accessed without removing the vaporization part 31, it is not preferable to dispose the heater 42 on this surface. However, it is permissible in the present invention to dispose a fixed heater on the surface closest to the gas supply piping 32 for some purpose. In addition, it is not preferable to dispose the heater 42 on the left or right surface of the vaporization part 31 since the left-right width of the vaporization part 31 has to be narrowed by the thickness of the heater 42 and thereby the volume of the vaporization part 31 is reduced. However, it is permissible in the present invention to dispose the heater 42 on the left or right surface of the vaporization part 31 at the expense of volume, for some purpose.

A set of the upper and lower heaters 42 shown in FIG. 7 are connected to a manipulator 5 constituted by a planar heater plate 53. A part of this heater plate 53, specifically an end part on the side of the opening surface 21 (namely on the opposite side to the flow channel 3) exists at a position which can be directly touched with a finger of a hand through the opening part which appears by removing the opening surface 21 of the case 2 in a state where the heater 42 is built in the vaporizer 1, and therefore the part of the heater plate 53 is accessible. By operating a part of the heater plate 53 with a finger of a hand, the heater 42 linked to the heater plate 53 can be displaced in a direction approaching to or receding from the flow channel 3 including the vaporization part 31. By bending end parts 531 of a planar plate constituting the heater plate 53 at a right angle in a direction opposite to the vaporization part 31, strength of the heater plate 53 against bending stress can be increased. Thereby, since the heater 42 can be fixed in close contact with the vaporization part 31, heating efficiency of the vaporization part 31 by the heater 42 is improved.

In FIG. 7, the heater 42 can be slid and displaced in the vicinity of the surface of the vaporization part 31. Since the movable range of the heater 42 is defined by the surface of the vaporization part 31, the vaporization part 31 is equivalent to a guide in the second embodiment of the present invention. The heater plate 53 comprises a locking part 73 that is an opening part formed in a part bent to the opposite side of the vaporization part 31 at an end part close to the fixing surface 22 of the case 2. This locking part 73 can be inserted with pins 311 provided in the vaporization part 31 to fix the position of the heater plate 53. Furthermore, the heater plate 53 comprises fastening parts 74 consisting of screws on the side close to the opening part 21 of the case 2. The locking part 73, the pins 311 and the fastening parts 74 are equivalent to the stoppers in the second embodiment.

When fixing the heater 42 to the vaporization part 31, first, the heater plate 53 is operated by a finger of a hand to slide the heater 42 along the vaporization part 31, and the pins 311 are inserted into the locking parts 73 on the back side (depth side). Next, the fastening parts 74 consisting of screws are fastened to the vaporization part 31 using a screwdriver. When removing the heater 42, operation reverse to this should be done. In the above-mentioned operation, since the screws exist at accessible positions, they can be easily fastened or unfastened using an ordinary screwdriver. When thumbscrews are used instead of the screws, the operation can be done with a finger of a hand without using a screwdriver.

### <Modification 3>

FIGS. 8 to FIG. 10 are perspective diagrams for showing a modification of the second embodiment. FIG. 8 is a perspective diagram for showing a tank which constitutes a vaporization part 31. Among the wall surfaces constituting the tank, the lower part 312 of the tank is constituted by a plate-like part with larger thickness than those of other wall surfaces, and has two insertion holes 63. Holes for screwing screws to fix a cover 75 which will be mentioned later are formed close to the opening parts of the insertion holes 63.

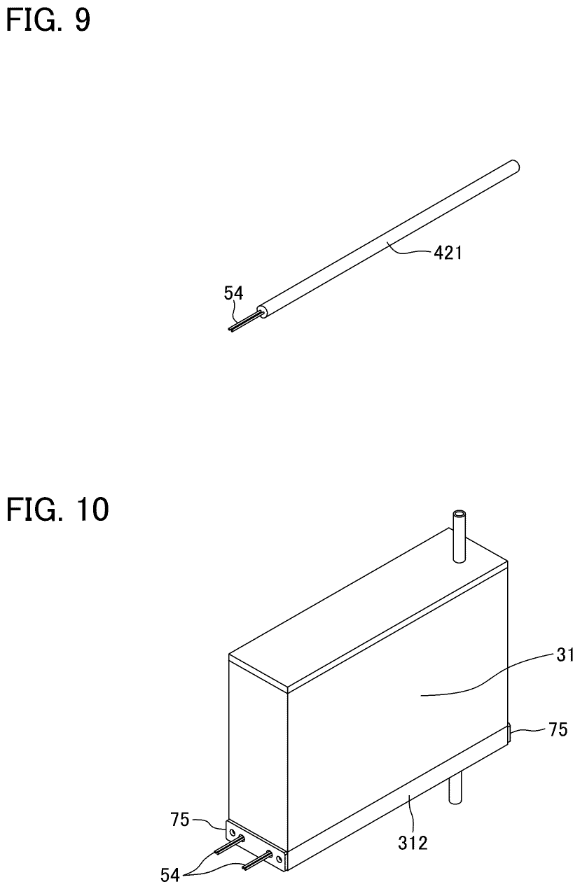

FIG. 9 is a perspective diagram for showing a cartridge heater 421. The cartridge heater 421 is a rod-shaped heater having a structure in which a heating element is built in a stainless steel tube closed at one end. Two lead wires 54 exit from an end part of the stainless steel tube, which is not closed. The lead wires 54 are electrically connected with the heating element inside the tube. By connecting a power source with the lead wires 54 to supply electric power, the cartridge heater 421 can generate heat.

FIG. 10 is a perspective diagram for showing a state where two cartridge heaters 421 are built into the vaporizer 31. In order to build the cartridge heaters 421 into the vaporization part 31, first, the cartridge heaters 421 are inserted into the insertion holes 63 shown in FIG. 8. At this point, the insertion holes 63 perform a function of the guide 6 in this modification. When the insertion holes 63 penetrate the lower part 312 of the tank, the end parts on the back side (depth side) of the insertion holes 63 are closed in advance by a cover 75. Next, in a state where the lead wires 54 of the cartridge heater 421 are inserted through a small hole in the other cover 75, the cover 75 is fixed to the front side of the lower part of tank 312 by screws not shown such that the cartridge heater 421 cannot be pulled out. In this case, the two covers 75 perform the function of the stopper 7 in this modification. On the other hand, when the insertion hole 63 does not penetrate the lower part 312 of the tank, namely, the insertion holes 63 are formed to have a length (depth) corresponding to the cartridge heater 421 and the end part on the back side (depth side) of the insertion holes 63 are closed in the first place, in a state where the lead wires 54 of the cartridge heater 421 are inserted through a small hole in one cover 75, the cover 75 is fixed to the front side of the lower part of tank 312 by screws not shown such that the cartridge heater 421 cannot be pulled out. In this case, the cover 75 and the end parts on the back side (depth side) of the insertion holes 63 perform the function of the stopper 7 in this modification. When removing the cartridge heater 421, operation reverse to the above should be done. When removing the cartridge heater 421 from the insertion hole 63, the lead wires 54 perform the function of the manipulator 5 in this modification.

When a precursor is heated in the vaporization part 31 to generate a material gas, heat is lost through vaporization or sublimation. For this reason, in order to efficiently generate the material gas in the vaporization part 31, it is preferable to adopt a heater 4 with large wattage. The cartridge heater 421 is generally suitable for heating the vaporization part 31 since it has higher wattage and a higher heat resistance temperature than the rubber heater 44.

### 4. Third Embodiment

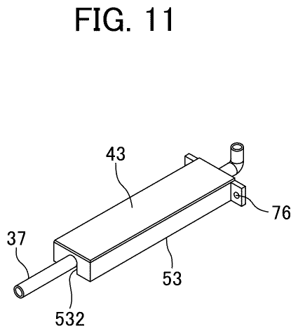

A third embodiment of the present invention will be explained using FIG. 11. FIG. 11 is a perspective diagram for showing an example of a heater 43 which heats the precursor supply piping 37. As mentioned above, the precursor supply piping 37 may be heated for the purpose of discharging the precursor remaining in the precursor supply piping 37 to the outside of the vaporizer 1. The heater shown in FIG. 11 is an example of a heater 43 used in such cases. The heater 43 is constituted by a flat plate-shaped heater and is connected to the heater plate 53 having a flat shaped part. At least a part of this heater plate 53, specifically the end part on the opening surface 21 side, is accessible since it exists at a position which can be directly touched with a finger of a hand through the opening part which appears by removing the opening surface 21 of the case 2 in a state where the heater 43 is built in the vaporizer 1. By operating a part of the heater plate 53 with a finger of a hand, the heater 43 linked with the heater plate 53 can be displaced in a direction approaching to or receding from the flow channel 3 including the precursor supply piping 37.

In FIG. 11, the heater plate 53 comprises a concave part 532 into which the precursor supply piping 37 enters. By sliding the heater plate 53 along the surface of the precursor supply piping 37, the heater 43 can be displaced. Since the movable range of the heater 43 is defined by the precursor supply piping 37, the precursor supply piping 37 is equivalent to the guide in the third embodiment of the present invention. The heater plate 53 comprises an opening hole 76 on the side close to the fixing surface 22 of the case 2. This opening hole 76 can be fixed by inserting a pin provided in the case 2 thereinto. The opening hole 76 and the pin are equivalent to the stopper in the third embodiment. As in the case of the second embodiment shown in FIG. 7, the heater plate 53 can be further fixed by screws or other fastening parts.

When fixing the heater 43 to the precursor supply piping 37, the heater plate 53 is operated with a finger of a hand to slide the heater 43 along the precursor supply piping 37 and insert the pin into the opening hole 76 on the back side (depth side). When the heater plate 53 comprises screws as fastening parts as mentioned above, the screws are fastened to the case 2 using a screwdriver. When removing the heater 43, operation reverse to this should be done. In the third embodiment, the heater 43 may be temporarily installed only when heating the precursor supply piping 37 as a precursor is changed. In this case, the precursor supply piping 37 may be heated in a state where the heater 43 is simply placed on the top of the precursor supply piping 37 without fixing the heater 43 with screws.

### 5. Evacuation of Electric Wiring, Etc.

In a preferred embodiment, the vaporizer 1 according to the present invention is configured such that electrical wiring and tubing existing in the movable range of the heater 4 can be temporarily evacuated from the movable range by deforming themselves and/or releasing their connectors. Since the vaporizer 1 according to the present invention is narrow in the left-right direction and the whole unit is designed to be compact, a space inside the case 2 is small as exemplified in FIG. 1. In particular, there is little extra space since the vaporization part 31 is installed such that the vaporization part 31 occupies a large part of the vaporizer 1 in the width and depth directions. For this reason, the electrical wiring for transmitting electrical signals and electric power necessary to operate the vaporizer 1 and tubing for sending compressed air to drive an air valve are contained in areas other than an area where the vaporization part 31 is installed, for example, in a space between the flow control device 35 and the opening surface 21 in the case 2, or the like.

However, this space corresponds just to the movable range when replacing the heater 4 which heats the flow channel 3. Therefore, the presence of the electrical wiring and tubing may obstruct the displacement when replacing the heater 4. In a preferred embodiment, the vaporizer 1 according to the present invention is configured such that the electrical wiring and tubing existing in the movable range of the heater 4 can be temporarily evacuated from the movable range. Thereby, the replacement of the heater 4 is facilitated, since the obstacles preventing the displacement of the heater 4 are removed.

The evacuation of the electrical wiring and tubing can be carried out by deformation of themselves. In this case, for example, by configuring the electrical wiring and tubing longer than the required length and temporarily pulling the electrical wiring and tubing outward from the opening surface 21 of the case 2 of the vaporizer 1 or temporarily moving the electrical wiring and tubing to the side of another heater 4 other than the heater 4 to be replaced, the heater 4 can be evacuated from the movable range of the heater 4. After the failed heater 4 is removed from the vaporizer 1 and the back-up heater 4 is installed, the evacuated electrical wiring and tubing can be returned to their original positions.

The evacuation of the electrical wiring and tubing can also be performed by releasing connectors. In this case, for example, the connectors are provided in the middle of the electrical wiring and tubing, and the connectors are released when the heater 4 is replaced. Then, parts of the electrical wiring and tubing separated at positions of the connectors can be evacuated from the movable range of the heater 4 by temporarily pulling the parts out of the opening surface 21 of the case 2 of the vaporizer 1 or by temporarily moving the parts to the side of another heater 4 other than the heater 4 to be replaced. After the failed heater 4 is removed from the vaporizer 1 and the back-up heater 4 is installed, the released connectors can be rejoined and returned to their original positions.

In the above description, the embodiments of the present invention have been explained in detail with reference to the drawings. These explanations and drawings are merely for exemplifying the embodiments of the present invention, and embodiments of the present invention is not limited to the embodiments exemplified herein. The present invention may be implemented by modifying at least a part of its configuration unless it departs from a technical concept explained herein, whether or not explicitly described in the specification and drawings.

1. A vaporizer for vaporizing a precursor of a material gas for semiconductor manufacture to generate said material gas, comprising:
a flow channel through which said material gas flows,
one or more replaceable heaters which heat said flow channel and are installed at a position where it is difficult or impossible for an operator performing maintenance of said vaporizer to directly touch said heaters with a finger of a hand of said operator,
a manipulator which is connected with said heater and displaces said heater in a direction approaching said flow channel or in a direction going away from said flow channel, and at least a part of said manipulator exists at a position where said operator can directly touch said manipulator with a finger of a hand of said operator,
a guide which determines a movable region of said heater, and
a stopper which fixes a positional relation between said manipulator and said guide.

2. The vaporizer according to claim 1, further comprising a case which houses said flow channel, said heaters, said manipulator, said guide and said stopper, wherein:
said case has at least one opening surface which can be detached even in a state where another vaporizer or other structure is installed adjacent to said vaporizer,
said heaters are installed at a position where it is difficult or impossible for said operator to directly touch said heaters with a finger of a hand of said operator through an opening part which appears by detaching said opening surface, in a state where a positional relation between said manipulator and said guide is fixed by said stopper, and
at least a part of said manipulator exists at a position where said operator can directly touch said manipulator with a finger of a hand of said operator through said opening part.

3. The vaporizer according to claim 2, wherein:
at least a part of said manipulator exists on a side of said opening surface from a position 30 mm away toward the inside of said case from said opening surface.

4. The vaporizer according to claim 1, wherein:
said manipulator is constituted by a cylindrical member,
said guide is constituted by a rod-shaped member which can be inserted in said cylindrical member to displace said cylindrical member and has a male screw at an end part, and
said stopper is constituted by a nut which has a female screw corresponding to said male screw and fixes said cylindrical member to said rod-shaped member by being screwed to the end part of said rod-shaped member.

5. The vaporizer according to claim 1, wherein:
said manipulator is constituted by a rod-shaped member,
said guide is constituted by a cylindrical member in which said rod-shaped member can be inserted to displace said rod-shaped member, and
said stopper is constituted by a cap which fixes said rod-shaped member to said cylindrical member by being fixed at the end part of said cylindrical member.

6. The vaporizer according to claim 2, wherein:
said manipulator is constituted by two extended parts extending from respective end parts of a set of two sheets of said heaters in the same in-plane directions as those of said heaters,
said guide is constituted by both side surfaces of said flow channel and a left side surface and a right side surface located outside of said both sides surface of said flow channel among surfaces of said case, and
said stopper is constituted by said opening surface and a connection part which connects said extended parts and.

7. The vaporizer according to claim 2, wherein:
said flow channel comprises a vaporization part which vaporizes said precursor to generate said material gas,
said heater is constituted by one or more planar heaters which heat said vaporization part,
said manipulator is constituted by a heater plate connected with said heater,
said stopper is constituted by a locking part prepared on a side further from said opening surface and a fastening part prepared on a side closer to said opening surface, and
said heater is fixed to a surface of said vaporization part by fastening said fastening part on the surface of said vaporization part.

8. The vaporizer according to claim 1, wherein:
said flow channel comprises a vaporization part which vaporizes said precursor to generate said material gas,
said vaporization part comprises one or more insertion holes,
said heater is constituted by one or more rod-shaped cartridge heaters inserted in said insertion holes,
said manipulator is constituted by a lead wire which said cartridge heater comprises,
said stopper is constituted by a cover that is a tabular member comprising a small hole through which said lead wire is inserted, and
said cartridge heater is fixed to said insertion hole by fastening said cover on a surface of said vaporization part.

9. The vaporizer according to claim 2, wherein:
said flow channel comprises a vaporization part which vaporizes said precursor to generate said material gas and precursor supply piping which supplies said precursor to said vaporization part,
said heater is constituted by one or more planar heaters which heat said precursor supply piping,
said manipulator is constituted by a heater plate connected with said heater,
said stopper is constituted by a pin prepared on a fixing surface that is a surface opposite to said opening surface of said case and an opening hole formed on a side closer to said fixing surface of said heater plate, and
a positional relation between said heater plate and said precursor supply piping is fixed by inserting said pin in said opening hole.

10. The vaporizer according to claim 1, wherein:
said flow channel comprises one or more members chosen from a group consisting of a pressure gauge, a valve, a flow controller and a joint block.

11. The vaporizer according to claim 1, wherein:
a distance between the surface of said flow channel and the surface of said heater is 0.10 mm or more and 0.80 mm or less, in a state where the positional relation between said manipulator and said guide is fixed by said stopper.

12. The vaporizer according to claim 1, wherein:
electric wiring and tube existing in a movable region of said heater are configured so as to be able to temporarily evacuate from said movable region of said heater by deformation of themselves or release of a connector.
